(19) United States
(12) Patent Application Publication
(10) Pub. No.: US 2026/0327800 A1
(43) Pub. Date: Oct. 22, 2026

(54) FILM FORMING METHOD AND FILM FORMING SYSTEM

(71) Applicant: Tokyo Electron Limited, Tokyo (JP)

(72) Inventor: Isao GUNJI, Nirasaki City (JP)

(21) Appl. No.: 19/529,470

(22) Filed: Feb. 4, 2026

Related U.S. Application Data
(63) Continuation of application No. PCT/JP2024/026936, filed on Jul. 29, 2024.

(30) Foreign Application Priority Data
Aug. 10, 2023 (JP) 2023-130955

(51) Int. Cl. C23C 16/455; C23C 16/56

(52) U.S. Cl. CPC C23C 16/45546; C23C 16/56

(57) ABSTRACT

A film forming method of performing film formation using a batch-type film forming apparatus including a first chamber and a single-wafer-type modification apparatus including a second chamber, which includes: loading a plurality of substrates into the first chamber; forming a compound film on each of the plurality of substrates loaded into the first chamber; forming a carbon-containing protective film on each of the plurality of substrates inside the first chamber; unloading, from the first chamber, the plurality of substrates on each of which the carbon-containing protective film has been formed; loading one or several substrates, among the plurality of substrates unloaded from the first chamber, into the second chamber of the single-wafer-type modification apparatus; and performing modification processing on the one or several substrates inside the second chamber. A modified film is formed on the one or several substrates by the performing the modification processing.

### CROSS-REFERENCE TO RELATED APPLICATION

This application is a bypass continuation application of International Application No. PCT/JP2024/026936 having an international filing date of Jul. 29, 2024 and designating the United States, the international application being based upon and claiming the benefit of priority from Japanese Patent Application No. 2023-130955, filed on Aug. 10, 2023, the entire contents of which are incorporated herein by reference.

### TECHNICAL FIELD

The present disclosure relates to a film forming method and a film forming system.

### BACKGROUND

In a semiconductor device, an insulating film, a hard mask, and the like are provided. Among these, a compound film such as, for example, a silicon nitride film (SiN film), has been widely used.

In forming the SiN film, there are known a technique for forming a film on each of a plurality of substrates in a batch manner by a plasma-assisted atomic layer deposition (ALD) process using a vertical batch-type apparatus (for example, Patent Document 1), and a technique for forming a film on each of substrates one by one by the plasma-assisted ALD process using a single-wafer-type apparatus (for example, Patent Document 2).

### Prior Art Document

### Patent Documents

Patent Document 1: Japanese Patent Publication No. 6656103
Patent Document 2: Japanese Laid-Open Patent Publication No. 2019-163497

### SUMMARY

According to one embodiment of the present disclosure, there is provided a film forming method of performing film formation using a batch-type film forming apparatus including a first chamber and a single-wafer-type modification apparatus including a second chamber, the film forming method comprising: loading a plurality of substrates into the first chamber; forming a compound film on each of the plurality of substrates loaded into the first chamber; forming a carbon-containing protective film on each of the plurality of substrates inside the first chamber; unloading, from the first chamber, the plurality of substrates on each of which the carbon-containing protective film has been formed; loading one or several substrates, among the plurality of substrates unloaded from the first chamber, into the second chamber of the single-wafer-type modification apparatus; and performing modification processing on the one or several substrates inside the second chamber, wherein a modified film is formed on the one or several substrates by the performing the modification processing.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a flowchart illustrating a first embodiment of a film forming method.

FIGS. 2A-2F are cross-sectional process views illustrating one example of major operations of the first embodiment of the film forming method.

FIGS. 3A -3F are cross-sectional process views illustrating another example of the major operations of the first embodiment of the film forming method.

FIGS. 4A-4F are cross-sectional process views illustrating yet another example of the major operations of the first embodiment of the film forming method.

FIG. 5 is a flowchart illustrating a second embodiment of a film forming method.

FIGS. 6A-6E are cross-sectional process views illustrating an example of major operations of the second embodiment of the film forming method.

FIG. 7 is a block diagram schematically illustrating an example of a film forming system used for implementing the film forming method.

FIG. 8 is a vertical cross-sectional view illustrating an example of a batch-type film forming apparatus in the film forming system of FIG. 7.

FIG. 9 is a horizontal cross-sectional view illustrating the batch-type film forming apparatus illustrated in FIG. 8.

FIG. 10 is a vertical cross-sectional view illustrating an example of a single-wafer-type modification apparatus in the film forming system of FIG. 7.

### DETAILED DESCRIPTION

Hereinafter, embodiments will be described with reference to the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Film Forming Method

### First Embodiment

First, a first embodiment of a film forming method will be described.

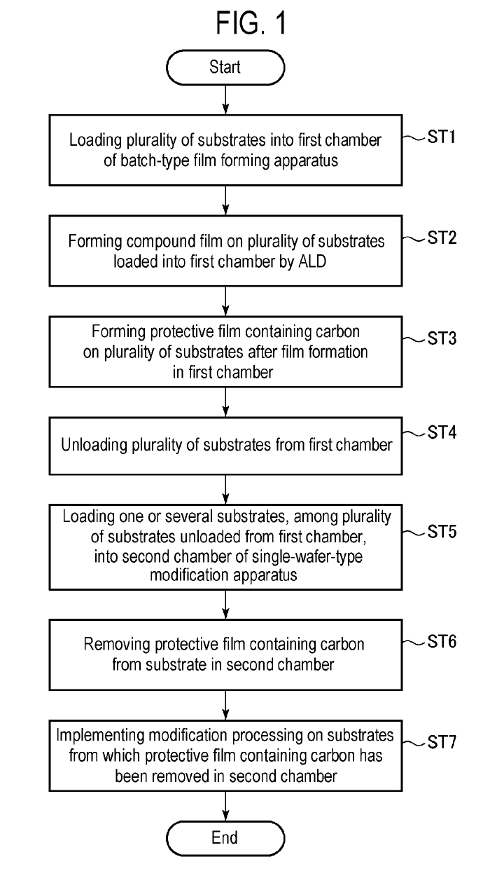

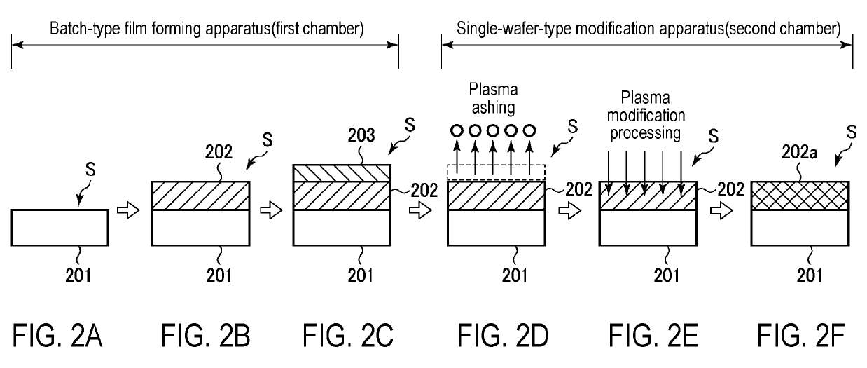

FIG. 1 is a flowchart illustrating the first embodiment of the film forming method, and FIGS. 2A-2F are cross-sectional process views illustrating major operations of the first embodiment of the film forming method.

In the first embodiment, film formation is performed using a film forming system provided with a batch-type film forming apparatus including a first chamber and a single-wafer-type modification apparatus including a second chamber.

The batch-type film forming apparatus refers to a film forming apparatus that performs film formation processing on a plurality of substrates of about 50 or more in a batch manner. As the batch-type film forming apparatus, a vertical-type film forming apparatus which performs film formation on the plurality of substrates (for example, about 50 to 175 substrates) stacked one above another in a vertical direction and placed inside a chamber, may be used.

The single-wafer-type modification apparatus refers to an apparatus that performs modification processing with respect to one substrate or on several substrates (about four substrates) on the same plane. As the single-wafer-type modification apparatus, an apparatus in which a stage is provided inside a chamber and one or several substrates are placed on the stage may be used to perform the modification processing.

First, the plurality of substrates are loaded into the first chamber of the batch-type film forming apparatus (Step ST1). As illustrated in FIG. 2A, a substrate S includes a base 201. Other films may be formed on the base 201. The base 201 is not particularly limited, but a semiconductor base represented by silicon is exemplified as a typical one.

Next, a compound film is formed on each of the plurality of substrates loaded into the first chamber by ALD (Step ST2). The compound film may be a nitrogen-containing film or an oxygen-carbon-containing film. In the present embodiment, the formed compound film has substantially the same composition as that of the compound film after modification, except for impurities. The film formation by ALD is performed by alternately supplying a raw material gas and a reaction gas into the first chamber, and repeating adsorption of the raw material gas and a reaction by the reaction gas. FIG. 2B illustrates a state in which a compound film 202 is formed on the base 201 of the substrate S illustrated in FIG. 2A. In addition, the case of forming the compound film by ALD has been exemplified here, but the compound film may also be formed by CVD.

Examples of the compound film include films used as an insulating film or a hard mask. In the case in which the compound film is the nitrogen-containing film, the compound film may be any of a SiN film, a SiCN film, a SiON film, a SiOCN film, a BN film, and a BCN film. In the case in which the compound film is the oxygen-carbon-containing film, the compound film may be a SiOC film. The SiOCN film is also the oxygen-carbon-containing film.

In the case of the SiN, SiCN, SiON, SiOCN, and SiOC films, a Si raw material gas is used as the raw material gas. a gas in which oxygen, nitrogen, or carbon is contained in a raw-material-gas molecular skeleton may be used as the Si raw material gas. Further, in the case of the SiN film, the nitrogen-containing gas is used as the reaction gas. In the case of the SiCN film, the nitrogen-containing gas and the carbon-containing gas are used as the reaction gas. In the case of the SiON film, the nitrogen-containing gas and the oxygen-containing gas are used as the reaction gas. Further, the case of the SiOC film, the carbon-containing gas and the oxygen-containing gas are used as the reaction gas. In the case of a SiOCN film, the nitrogen-containing gas, the carbon-containing gas, and the oxygen-containing gas are used as the reaction gas. A BN film and a BCN film may be formed using a B raw material gas as the raw material gas. In the case of the BN film, the nitrogen-containing gas is used as the reaction gas. In the case of the BCN film, the nitrogen gas and the carbon-containing gas are used as the reaction gas.

As the Si raw material gas, a silane-based compound gas, a chlorosilane-based compound gas, an aminosilane-based compound gas, a siloxane-based compound gas, an organic silicon-based compound gas, a trisilylamine (TSA) gas, or the like may be preferably used. Examples of the silane-based compound gas may include a SiH₄ gas and a Si₂H₆ gas. Examples of the chlorosilane-based compound gas may include a SiH₂Cl₂ gas and the like. Examples of the aminosilane-based compound gas may include dimethylaminosilane and the like. Examples of the siloxane-based compound gas may include tetraethoxysilane (TEOS) and the like. Examples of the organic silicon-based compound gas may include dimethyldimethoxysilane (DMDMOS) and the like. In forming the SiN film, a Cl-containing Si compound gas such as a chlorosilane-based compound may be preferably used as the Si raw material gas. Further, a B₂H₆ gas, a BCl₃ gas, an alkylborane gas, or the like may be preferably used as the B raw material gas. A NH₃ gas, a N₂ gas, or the like may be used as the nitrogen-containing gas. An O₂ gas, a H₂O gas, a H₂O₂ gas, a N₂O gas, a NO gas, or the like may be used as the oxygen-containing gas. Hydrocarbon gases such as a C₂H₄ gas, a C₂H₂ gas, a C₂H₆ gas, and a C₃H₆ gas may be used as the carbon-containing gas.

The film formation may be performed by a plasma-assisted ALD process (in the case of the film formation by CVD, a plasma-assisted CVD process) using plasma. By adding energy from the plasma, the film formation may be performed at a lower temperature. In particular, when high energy is required during the film formation, the plasma may be preferably used. In the film formation using the plasma, a batch-type plasma-assisted film forming apparatus in which a remote plasma source is added, may be used.

Next, a carbon-containing protective film is formed on each of the plurality of substrates which have been subjected to the film formation inside the first chamber (Step ST3). FIG. 2C illustrates a state in which a carbon-containing protective film 203 is formed on the substrate S on which the compound film 202 has been formed.

The carbon-containing protective film functions as a film that prevents oxidation of the compound film. Due to the presence of the carbon-containing protective film, the nitrogen-containing film or the oxygen-carbon-containing film is prevented from being oxidized when the substrate is exposed to atmosphere. A thickness of the carbon-containing protective film is preferably 10 nm or more from the viewpoint of obtaining an effective protective effect. Further, the thickness is preferably 100 nm or less in consideration of the ease of removal.

A carbon film may be used as the carbon-containing protective film. The carbon-containing protective film may be easily formed by introducing the carbon-containing gas or the like into the first chamber of the batch-type film forming apparatus. In the case in which the carbon-containing protective film is the carbon film, the carbon-containing gas may be introduced into the first chamber to perform the film formation by a chemical vapor deposition (CVD). Hydrocarbon gases such as a C₂H₄ gas, a C₂H₂ gas, a C₂H₆ gas, and a C₃H₆ gas may be used as the carbon-containing gas. In addition to the carbon-containing gas, a noble gas such as an Ar gas or a He gas may be added.

The carbon-containing protective film may also be formed by the plasma-assisted CVD using the plasma. By adding energy from the plasma, the film formation may be performed at a relatively low temperature. It is advantageous to use the plasma since the formation of the carbon film requires high energy.

Next, the plurality of substrates are unloaded from the first chamber (Step ST4). The plurality of unloaded substrates may be exposed to the atmosphere.

Next, one or several substrates, among the plurality of substrates unloaded from the first chamber, are loaded into the second chamber of the single-wafer-type modification apparatus (Step ST5).

Next, the carbon-containing protective film is removed from the substrate in the second chamber (Step ST6). At this time, the removal of the carbon-containing protective film is performed using a gas containing no oxygen. The processing at this time may be plasma ashing using plasma. FIG. 2D illustrates a state in which the carbon-containing protective film 203 of FIG. 2C is removed by the plasma ashing. The carbon-containing protective film such as the carbon film may be removed relatively easily by the plasma ashing. The reason why the gas containing no oxygen is used for the removal of the carbon-containing protective film is that when the carbon-containing protective film is removed using a gas containing oxygen, a surface of a film exposed after the removal may be oxidized.

As the gas containing no oxygen used for the plasma ashing, a reducing gas such as a H₂ gas or a NH₃ gas may be preferably used. An N₂ gas may also be used. These gases may be used alone or in combination of two or more. As the plasma, various types of plasma such as a capacitively coupled plasma, an inductively coupled plasma, and a microwave plasma may be used.

Next, modification processing is performed on the substrate from which the carbon-containing protective film has been removed inside the second chamber (Step ST7). In the present embodiment, the modification processing is performed on the film exposed after the carbon-containing protective film has been removed, that is, on the compound film. Thus, a portion or the entirety of the compound film becomes a modified film, that is, a modified compound film. The modification processing may be plasma modification processing using plasma. FIG. 2E illustrates a state in which the plasma modification processing is performed on the surface of the compound film 202 exposed after the removal of the carbon-containing protective film 203 of FIG. 2D, and FIG. 2F illustrates a state in which a modified film 202a is formed by the modification processing. In addition, although FIG. 2F illustrates an example in which the entire compound film 202 becomes the modified film 202a, a portion of the compound film 202 may become the modified film 202a. A depth of the modified film 202amay be 20 nm or less.

In the present embodiment, the modification processing is processing for improving a film quality of the compound film formed by the batch-type film forming apparatus. Specifically, by the modification processing, particularly by the plasma modification processing, impurities present in the compound film are removed, and dangling bonds are eliminated, which enhances a bonding state of a compound constituting the compound film.

A noble gas may be used as a gas used in the plasma modification processing. For example, an Ar gas, a He gas, or a mixed gas of these may be used. Further, a chemical gas may be added to the noble gas. As the chemical gas, a H₂ gas, a NH₃ gas, a N₂ gas, a hydrocarbon gas, or the like may be used. These gases may be used alone or in combination of two or more. Further, when the compound film is the SiOC film or the SiOCN film, the gas containing oxygen, for example, one or two or more of an O₂ gas, a H₂O gas, a H₂O₂ gas, a N₂O gas, and a NO gas may be added as the chemical gas. By adding the gas containing oxygen, an amount of oxygen in the compound film may be adjusted. As the plasma used in the plasma modification processing, various types of plasma such as a capacitively coupled plasma, an inductively coupled plasma, and a microwave plasma may be used.

By the film forming method as described above, it is possible to form the compound film, typically a compound film containing nitrogen or a compound film containing oxygen and carbon, with high productivity and good film quality.

In the related art, for example, in a case in which the batch-type film forming apparatus as disclosed in Patent Document 1 is used to form the SiN film by ALD, the film formation processing is performed on the plurality of substrates in a batch manner, which is advantageous for the productivity and is disadvantageous in obtaining the good film quality in low-temperature film formation that is currently required. In particular, the batch-type plasma-assisted film forming apparatus used when forming the SiN film requires remote plasma in terms of a structure thereof, which is disadvantageous in forming a high-quality SiN film at a low temperature.

On the other hand, in a case in which the single-wafer-type film forming apparatus as disclosed in Patent Document 2 is used to form the SiN film by ALD, direct plasma is used, which makes it possible to form a high-quality SiN film even at a low temperature, but needs to repeatedly form atomic layers by alternately supplying a Si raw material and a nitriding gas. This is disadvantageous in terms of productivity.

Therefore, in the present embodiment, after performing the process of forming the compound film on each of the plurality of substrates in a batch manner by the batch-type film forming apparatus, the carbon-containing protective film for oxidation prevention is formed, and subsequently the modification processing is performed on one or several substrates by a dedicated single-wafer-type modification apparatus. Thus, it is possible to obtain a high-quality compound film at a low temperature while maintaining high productivity. That is, since the basic film formation processing is performed by the batch-type film forming apparatus, the productivity is high. Further, even if the film quality of the compound film formed at this time is low, the high-quality compound film may be obtained by the subsequent modification processing using the single-wafer-type modification apparatus.

In this case, although the modification processing by the single-wafer-type modification apparatus is added to the film formation processing by the batch-type film forming apparatus, one round of modification processing is performed at a certain depth (<20 nm) in a batch manner. Thus, sufficiently high productivity is obtained as compared with a case in which the film formation is performed on each atomic layer by ALD in a single-wafer manner. Further, the carbon-containing protective film for oxidation prevention may be formed in a short period of time by introducing the carbon-containing gas using the batch-type film forming apparatus. Thus, even if such a process is added, the sufficiently high productivity may be maintained. Further, the carbon-containing protective film is collectively removed by ashing using the single-wafer-type modification apparatus. Thus, even if the process of removing the protective film is added, the sufficiently high productivity may be maintained.

Further, after the film formation, the modification processing is performed by the dedicated single-wafer-type modification apparatus. Thus, the modification processing may be performed under conditions (high power, low pressure and the like) which may not be implemented in the single-wafer-type film forming apparatuses in the related art. This increases a degree of freedom of the modification processing and makes it possible to perform the modification processing to a relatively deep position. Further, the modification processing is performed collectively at a certain depth (<20 nm) after forming the compound film. Thus, the compound film serves as a protective film for an underlying layer, which makes it possible to alleviate damage to the underlying layer in compared with the single-wafer-type ALD film forming apparatus that performs processing for each atomic layer in the related art. Alternatively, in a case in which the same amount of damage is generated, a stronger modification condition may be selected.

In addition, FIGS. 2A-2F illustrate an example in which the compound film 202 is formed on the base 201 of a planar shape, the carbon-containing protective film 203 is formed and removed by the plasma ashing, and subsequently, the plasma modification processing is performed on the compound film 202 to form the modified film 202a. However, the film formation is not limited thereto, and may also be applied to a case in which a patterned substrate is used for film formation such as a case where embedding is performed on a substrate having a recess formed therein, and a case in which a compound film is formed on a surface of the substrate having the recess formed therein, or the like.

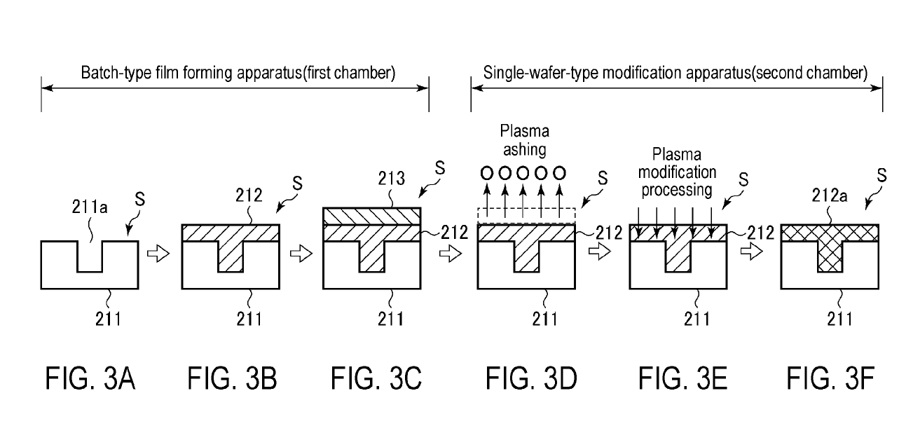

FIGS. 3A-3F illustrate an example in which the embedding is performed on the substrate having the recess formed therein. As illustrated in FIG. 3A, a base 211 having a recess 211a is prepared. As illustrated in FIG. 3B, a compound film 212 formed of, for example, a nitrogen-containing film or an oxygen-carbon-containing film, is formed to embed the recess 211a. Then, as illustrated in FIG. 3C, a carbon-containing protective film 213 is formed on the compound film 212. As illustrated in FIG. 3D, the protective film 213 is removed by thew plasma ashing. Next, as illustrated in FIG. 3E, the plasma modification processing is performed on the embedded compound film 212. As illustrated in FIG. 3F, a modified film 212a is formed. In this example, when the recess 211ais deep, it is desirable to appropriately set modification conditions (power, pressure and the like) so that a modification effect is obtained up to a deep position of the embedded compound film 212.

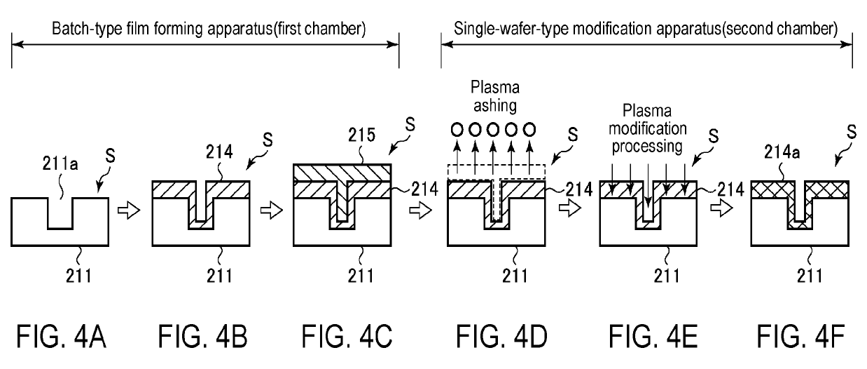

FIGS. 4A-4F illustrate an example in which a compound film is formed on a surface of a substrate having a recess formed therein so as not to be completely filled into the recess. As illustrated in FIG. 4A, similarly to FIG. 3A, the base 211 having the recess 211a is prepared. As illustrated in FIG. 4B, a compound film 214 formed of, for example, a nitrogen-containing film or an oxygen-carbon-containing film is formed. Then, as illustrated in FIG. 4C, a carbon-containing protective film 215 is formed on the compound film 214. As illustrated in FIG. 4D, the carbon-containing protective film 215 is removed by the plasma ashing. Next, as illustrated in FIG. 4E, the plasma modification processing is performed on the compound film 214. As illustrated in FIG. 4F, a modified film 214a is formed.

### Second Embodiment

Next, a second embodiment of the film forming method will be described.

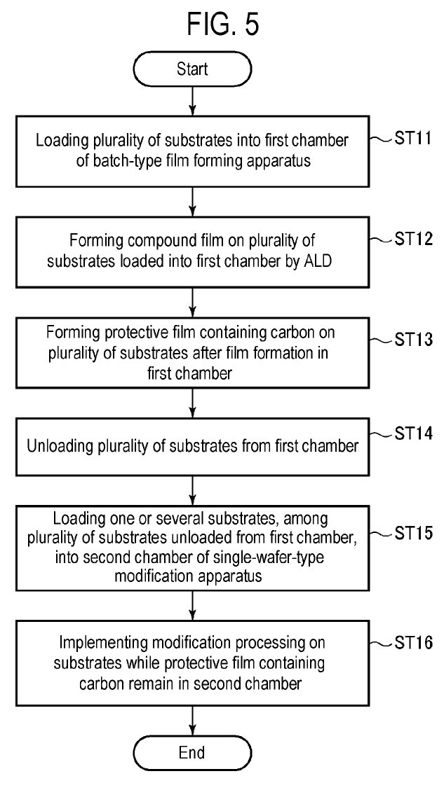

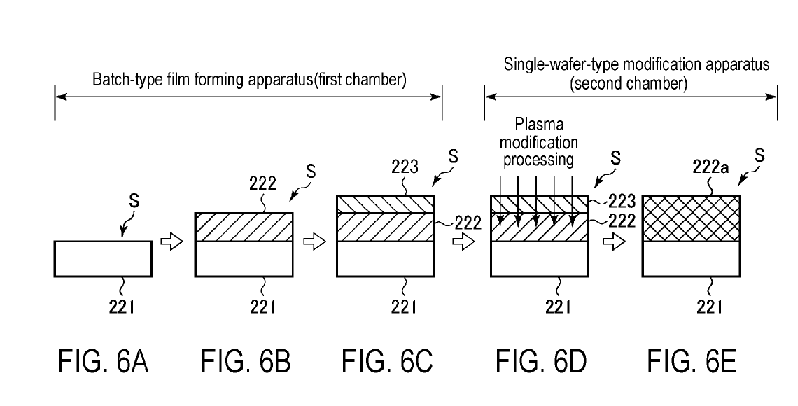

FIG. 5 is a flowchart illustrating the second embodiment of the film forming method, and FIGS. 6A-6E are cross-sectional process views illustrating major operations of the second embodiment of the film forming method.

In the present embodiment, as in the first embodiment, the film formation is performed using the film forming system provided with the batch-type film forming apparatus including the first chamber and the single-wafer-type modification apparatus including the second chamber.

First, the plurality of substrates are loaded into the first chamber of the batch-type film forming apparatus (Step ST11). As illustrated in FIG. 6A, the substrate S includes the base 221. Another film may be formed on the base 221. The base 221 is not particularly limited, but a semiconductor base is exemplified as a typical one, as in the first embodiment.

Next, a compound film is formed on the plurality of substrates loaded into the first chamber of the batch-type film forming apparatus by ALD (Step ST12). The compound film may be formed by CVD, as in the first embodiment. In the present embodiment, the compound film functions as a precursor of a modified film, and a composition of the film to be formed is determined in consideration of a composition of the modified film since carbon in the protective film is mixed with the film during the modification processing to be described later. The compound film in the present embodiment may be a film containing nitrogen or a film containing oxygen and carbon after modification. Specifically, in addition to the SiN film, the SiCN film, the SiON film, the SiOCN film, the BN film, the BCN film, and the SiOC film exemplified in the first embodiment, a SiO film may also be used. FIG. 6B illustrates a state in which a compound film 222 is formed on the base 221 of the substrate S illustrated in FIG. 6A.

Next, a carbon-containing protective film is formed on each of the plurality of substrates which has been subjected to the film formation processing inside the first chamber (Step ST13). FIG. 2C illustrates a state in which a carbon-containing protective film 223 is formed on the substrate S on which the compound film 222 is formed.

Next, the plurality of substrates are unloaded from the first chamber (Step ST14). The plurality of unloaded substrates may be exposed to the atmosphere.

Next, one or several substrates, among the plurality of substrates unloaded from the first chamber, are loaded into the second chamber of the single-wafer-type modification apparatus (Step ST15).

Steps ST11 to ST15 above are basically performed in the same manner as Steps ST1 to ST5 of the first embodiment.

In the present embodiment, next, the modification processing is performed on the substrate in a state in which the carbon-containing protective film remains inside the second chamber (Step ST16). Thus, carbon in the carbon-containing protective film is mixed with the compound film to form the modified film. The modification processing may be plasma modification processing using plasma. FIG. 6D illustrates a state in which the plasma modification processing is performed in a state in which the carbon-containing protective film 223 of FIG. 6C remains, and FIG. 6E illustrates a state in which a modified film 222a is formed by the modification processing. In addition, although FIG. 6E illustrates an example in which the entire compound film 222 becomes the modified film 222a, a portion of the compound film 222 may become the modified film 222a. A depth of the modified film 222a may be 20 nm or less.

In the present embodiment as well, the modification processing is processing for improving a film quality of the compound film formed by the batch-type film forming apparatus. Specifically, by the modification processing, particularly the plasma modification processing, carbon in the carbon-containing protective film is mixed with the compound film to adjust the film composition. Further, impurities in the compound film are removed and dangling bonds are eliminated to enhance a bonding state of a compound constituting the compound film.

Since the carbon is mixed with the compound film during the modification processing in this way, for example, when the compound film is the SiN film or the SiON film, the modified film becomes the SiNC film or the SiOCN film. Further, when the compound film is the BN film, the modified film becomes the BCN film. When the compound film is the SiO film, the modified film becomes the SiOC film. When the compound film is a carbon-containing film such as the SiCN film, the BCN film, the SiOC film, or the SiOCN film, the composition of the modified film shifts to carbon-rich. The composition of the modified film may be adjusted according to the thickness of the carbon-containing protective film and conditions of modification processing.

A noble gas may be used as the gas used in the plasma modification processing. For example, an Ar gas, a He gas, or a mixed gas thereof may be used. Further, a chemical gas may be added to the noble gas. As the chemical gas, a H₂ gas, a NH₃ gas, a N₂ gas, or the like may be used. These gases may be used alone or in combination of two or more. As the plasma used in the plasma modification processing, various types of plasma such as a capacitively coupled plasma, an inductively coupled plasma, and a microwave plasma may be used. Further, when the compound film is the SiO film, the SiON film, the SiOC film, or the SiOCN film, in addition to the above, an oxygen-containing gas for adjusting an amount of oxygen, for example, an O₂ gas, a H₂O gas, a H₂O₂ gas, a N₂O gas, or a NO gas may be used as the chemical gas.

In the present embodiment as well, after performing a process of collectively forming the compound film on each of the plurality of substrates by the batch-type film forming apparatus, the carbon-containing protective film is formed, and thereafter, the modification processing is performed on each substrate by the dedicated single-wafer-type modification apparatus. Thus, a high-quality compound film may be obtained at a low temperature while maintaining high productivity.

In the present embodiment, other effects obtained in the first embodiment may also be obtained. Further, since the carbon-containing protective film is not removed in the present embodiment, the productivity may be further increased as much.

### Film Forming System

Next, a film forming system for carrying out the above-described film forming method will be described.

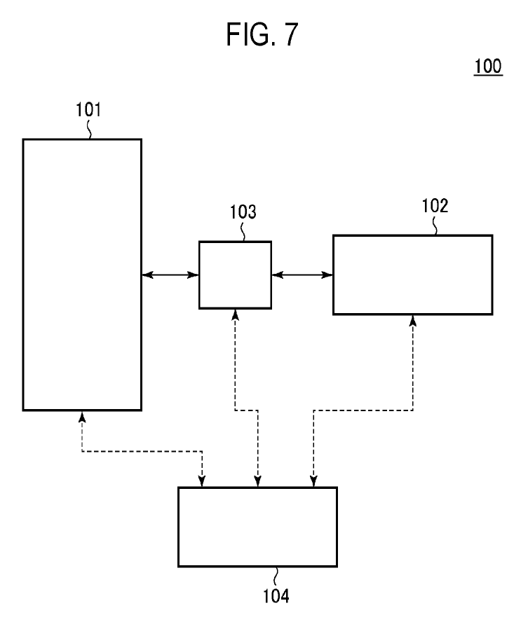

FIG. 7 is a block diagram schematically illustrating an example of the film forming system for carrying out the film forming method. As illustrated in FIG. 7, a film forming system 100 is provided with a batch-type film forming apparatus 101 including a first chamber, a single-wafer-type modification apparatus 102 including a second chamber, a transfer device 103, and a control device 104.

The batch-type film forming apparatus 101 is configured to load a plurality of substrates into a chamber and to perform film formation processing on each of the substrates in a vacuum atmosphere. As the batch-type film forming apparatus 101, a vertical-type film forming apparatus (to be described later) for performing the film formation on the plurality of substrates (for example, about 50 to 175 substrates) is arranged inside the chamber (the first chamber) while being stacked one above another in a vertical direction, may be used. Further, the batch-type film forming apparatus 101 may include a plasma source.

The single-wafer-type modification apparatus 102 performs the modification processing on films of one or several substrates, which have been subjected on the film formation and are placed on a stage inside the chamber (the second chamber), in a vacuum atmosphere. The single-wafer-type modification apparatus 102 may include a plasma source. Further, a plurality of single-wafer-type modification apparatuses 102 may be provided.

The transfer device 103 is configured to transfer the substrate in an atmospheric atmosphere. Specifically, the transfer device 103 performs loading of the substrate into the batch-type film forming apparatus 101, transfer of the substrate from the batch-type film forming apparatus 101 to the single-wafer-type modification apparatus 102, and unloading of the substrate from the single-wafer-type modification apparatus 102. Further, the transfer device 103 performs removal of the substrate from a substrate holder (not illustrated) that holds the substrate and delivery of the substrate to the substrate holder. The transfer device 103 may be configured to include a first transferor that collectively loads or unloads a plurality of substrates (for example, 5 to 25 substrates) held by the holder into or from the batch-type film forming apparatus 101, and a second transferor that loads or unloads one or several substrates into or from the single-wafer-type modification apparatus 102.

The control device 104 includes a CPU (computer), and controls the batch-type film forming apparatus 101, the single-wafer-type modification apparatus 102, and the transfer device 103. The control device 104 causes the batch-type film forming apparatus 101, the single-wafer-type modification apparatus 102, and the transfer device 103 to execute operations for the film formation based on a processing recipe.

In the film forming system 100 configured as above, under the control of the control device 104, first, the transfer device 103 loads the plurality of substrates (e.g., 50 to 175 substrates) into the first chamber of the batch-type film forming apparatus 101. Then, the compound film is formed on each of the plurality of substrates inside the first chamber. Subsequently, the carbon-containing protective film is formed. Next, the transfer device 103 unloads the plurality of substrates from the first chamber of the batch-type film forming apparatus 101, and loads one or several among the plurality of substrates into the second chamber of the single-wafer-type modification apparatus 102. Next, in the case of the film forming method of the first embodiment, the removal of the carbon-containing protective film from each substrate is performed, and subsequently, the modification processing is performed on each substrate inside the second chamber of the single-wafer-type modification apparatus 102. Further, in the case of the film forming method of the second embodiment, the modification processing is performed on each substrate inside the second chamber of the single-wafer-type modification apparatus 102 while leaving the carbon-containing protective film on each substrate. After the modification processing is performed on each substrate, each substrate is unloaded from the second chamber. The processing in the single-wafer-type modification apparatus 102 is repeated until the modification processing is performed on all of the plurality of substrates unloaded from the batch-type film forming apparatus 101.

In addition, the film forming system is not limited to being integrally configured as a specific system as illustrated in FIG. 7, as long as the film forming method of the first or second embodiment can be carried out. For example, even if the batch-type film forming apparatus and the single-wafer-type modification apparatus are provided separately in the film forming system and do not apparently constitute an integrated system, such a system may be the film forming system as long as it can carry out the above-described film forming method. That is, even if the batch-type film forming apparatus and the single-wafer-type modification apparatus are provided in separate systems and use a transfer container called a front opening unified pod (FOUP) to transfer the substrates to the other, such systems may constitute the film forming system described herein as long as they can carry out the above-described film forming method. In this case, for example, the film formation by the batch-type film forming apparatus, the modification by the single-wafer-type modification apparatus, and the transfer of the substrate may be controlled by a host computer of a semiconductor factory.

### Example of Batch-Type Film Forming Apparatus

Next, an example of the batch-type film forming apparatus 101 will be described. Here, a film forming apparatus for forming the SiN film will be described as an example.

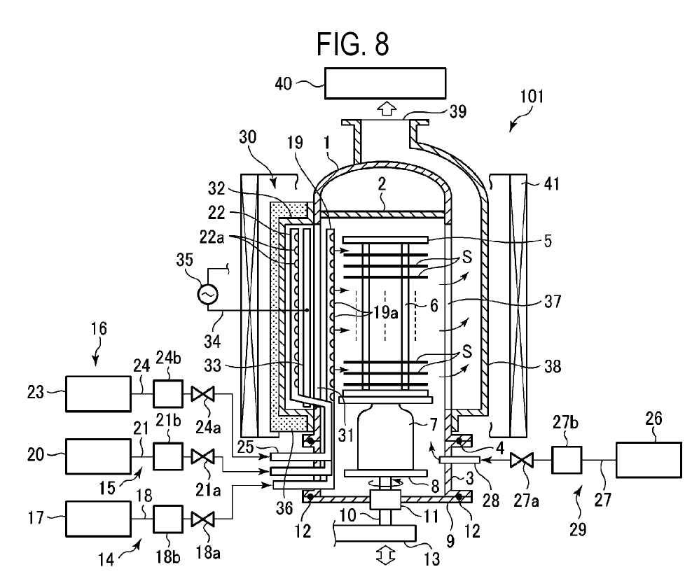

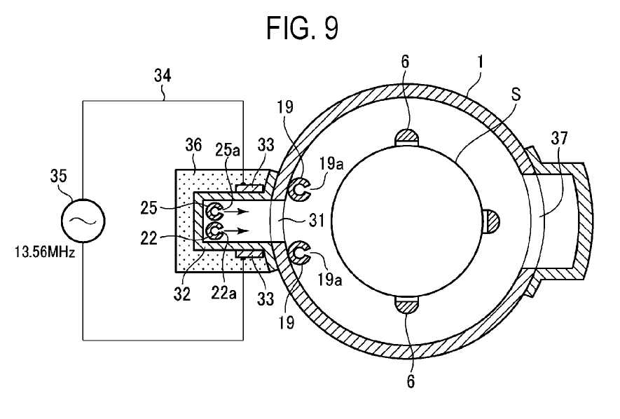

FIG. 8 is a vertical cross-sectional view illustrating the example of the batch-type film forming apparatus 101, and FIG. 9 is a horizontal cross-sectional view of the batch-type film forming apparatus illustrated in FIG. 8.

The batch-type film forming apparatus 101 of this example is configured as a plasma-assisted vertical-type film forming apparatus, and includes a first chamber 1 having a roof in a cylindrical shape and a lower end opening. The first chamber 1 is formed of, for example, quartz as a whole. A quartz ceiling plate 2 is provided in the vicinity of an upper end portion of an interior of the first chamber 1 so that a region below the ceiling plate 2 is sealed. Further, a metal-made manifold 3 molded in a cylindrical shape is connected to the lower end opening of the first chamber 1 via a sealing member 4 such as an O-ring.

The manifold 3 supports a lower end of the first chamber 1. A quartz-made substrate holder 5 in which the plurality of substrates S, for example, 50 to 175 substrates, are placed in multiple stages, is inserted into the first chamber 1 from below the manifold 3. The substrate S may be a semiconductor wafer (silicon wafer), and the substrate holder 5 may be a wafer boat. The substrate holder 5 includes three rods 6 (see FIG. 9), and each of the plurality of substrates S are supported by grooves (not illustrated) formed in the rods 6.

The substrate holder 5 is placed on a table 8 via a quartz-made heat-retention vessel 7. The table 8 is supported on a rotary shaft 10 that penetrates a metal (stainless steel) lid 9 for opening or closing a lower end opening of the manifold 3.

Further, a magnetic fluid seal 11 is provided around a penetrating portion of the rotary shaft 10 to airtightly seal and rotatably support the rotary shaft 10. Further, a sealing member 12 is interposed between a peripheral portion of the lid 9 and a lower end portion of the manifold 3 to maintain a sealing property of the interior of the first chamber 1.

The rotary shaft 10 is attached to a tip of an arm 13 supported by an elevating mechanism (not illustrated). The substrate holder 5, the lid 9, and the like are integrally moved up or down so that they are inserted to or removed from the interior of the first chamber 1. In addition, the table 8 may be fixed to the side of the lid 9, and the film formation on the substrate S may be performed without rotating the substrate holder 5.

Further, the batch-type film forming apparatus 101 includes a Si raw material gas supply mechanism 14 for supplying a Si raw material gas into the first chamber 1, a nitrogen-containing gas supply mechanism 15 for supplying a nitrogen-containing gas into the first chamber 1, and a carbon-containing gas supply mechanism 16 for supplying a carbon-containing gas into the first chamber 1. Further, the batch-type film forming apparatus 101 includes an inert gas supply mechanism 29 for supplying an inert gas, for example, an Ar gas, into the first chamber 1.

The Si raw material gas supply mechanism 14 includes a Si raw material gas source 17, a gas pipe 18 for guiding the Si raw material gas from the Si raw material gas source 17, and a gas dispersion nozzle 19 connected to the gas pipe 18 to guide the Si raw material gas into the first chamber 1. As the Si raw material gas, a Cl-containing Si compound gas such as a SiH₂Cl₂ gas may be preferably used.

The nitrogen-containing gas supply mechanism 15 includes a nitrogen-containing gas source 20, a gas pipe 21 for guiding the nitrogen-containing gas from the nitrogen-containing gas source 20, and a gas dispersion nozzle 22 connected to the gas pipe 21 to guide the nitrogen-containing gas into the first chamber 1. For example, a NH₃ gas or a N₂ gas may be used as the nitrogen-containing gas. Both of these may be used.

The carbon-containing gas supply mechanism 16 includes a carbon-containing gas source 23, a gas pipe 24 for guiding the carbon-containing gas from the carbon-containing gas source 23, and a gas dispersion nozzle 25 connected to the gas pipe 24 to guide the carbon-containing gas into the first chamber 1. For example, a hydrocarbon gas such as a C₂H₄ gas, C₂H₂ gas, C₂H₆ gas, a C₃H₆ gas or the like may be used as the carbon-containing gas.

The gas dispersion nozzles 19, 22 and 25 are made of quartz, and penetrate inwardly through a sidewall of the manifold 3 and then are bent upward to extend vertically. A plurality of gas discharge holes 19a, 22a and 25a are formed at predetermined intervals in vertical portions of the gas dispersion nozzles 19, 22 and 25, respectively, over a vertical length corresponding to a substrate support range of the substrate holder 5. Gas may be discharged about uniformly in a horizontal direction from the respective gas discharge holes 19a, 22a and 25a toward the first chamber 1. In addition, although two gas dispersion nozzles 19 are provided in this example, a single gas dispersion nozzle may be provided.

The inert gas supply mechanism 29 includes an inert gas source 26, a gas pipe 27 for guiding an inert gas from the inert gas source 26, and a gas nozzle 28 connected to the gas pipe 27 and penetrating the sidewall of the manifold 3. The gas nozzle 28 is constituted as a short quartz tube.

The gas pipes 18, 21, 24 and 27 are provided with on-off valves 18a, 21a, 24a and 27a, and flow-rate controllers 18b, 21b, 24b and 27b, respectively.

A plasma generation mechanism 30 is formed in a portion of the sidewall of the first chamber 1. The plasma generation mechanism 30 plasmarizes the nitrogen-containing gas and the carbon-containing gas, and is configured as a remote plasma source. The plasma generation mechanism 30 includes a plasma partition wall 32 airtightly welded to an outer wall of the first chamber 1. The plasma partition wall 32 is made of, for example, quartz. The plasma partition wall 32 has a concave cross-sectional shape, and covers an opening 31 formed in the sidewall of the first chamber 1. The opening 31 is formed in a vertically elongated shape so as to cover all of the substrates S supported by the substrate holder 5 in the vertical direction. The gas dispersion nozzle 22 for discharging the nitrogen-containing gas and the gas dispersion nozzle 25 for discharging the carbon-containing gas are arranged in an inner space defined by the plasma partition wall 32, that is, inside a plasma generation space. In addition, two gas dispersion nozzles 19 are provided at positions sandwiching the opening 31 of the inner wall of the first chamber 1 outside the plasma generation space.

Further, the plasma generation mechanism 30 further includes a pair of elongated plasma electrodes 33 arranged on outer surfaces of both sidewalls of the plasma partition wall 32 so as to face each other in the vertical direction, and a radio-frequency power supply 35 connected to each of the pair of plasma electrodes 33 via a power supply line 34 to supply radio-frequency power to the pair of plasma electrodes 33. The radio-frequency power supply 35 applies a radio-frequency voltage of, for example, 13.56 MHz to the pair of plasma electrodes 33. Thus, a radio-frequency electric field is applied inside the plasma generation space defined by the plasma partition wall 32. The nitrogen-containing gas discharged from the gas dispersion nozzle 22 and the carbon-containing gas discharged from the gas dispersion nozzle 25 are plasmarized in the plasma generation space to which the radio-frequency electric field is applied, and are transferred, as a plasma gas containing active species, into the first chamber 1 via the opening 31.

An insulating protective cover 36 is attached to an outer side of the plasma partition wall 32 so as to cover the plasma partition wall 32. A coolant passage (not illustrated) is provided in an inner portion of the insulating protective cover 36. The plasma electrodes 33 are cooled by flowing a coolant such as a cooled nitrogen gas through the coolant passage.

An exhaust port 37 for evacuating the interior of the first chamber 1 is provided in a sidewall portion of the first chamber 1 facing the gas dispersion nozzles 19, 22 and 25. The exhaust port 37 is formed in a vertically elongated shape. An exhaust-port cover member 38, which is molded to have a U-shaped cross-sectional shape so as to cover the exhaust port 37, is attached to a portion of the first chamber 1 corresponding to the exhaust port 37. The exhaust-port cover member 38 extends upward along the sidewall of the first chamber 1, and defines a gas outlet 39 at the top of the first chamber 1. Further, an exhaust device 40 including a vacuum pump and the like is connected to the gas outlet 39. The interior of the first chamber 1 is exhausted via the gas outlet 39 by the exhaust device 40. Further, a cylindrical heating mechanism 41 for heating the first chamber 1 and the plurality of substrates S inside the first chamber 1 is provided so as to surround an outer periphery of the first chamber 1.

In this batch-type film forming apparatus 101, after the SiN film is formed as the compound film on each of the plurality of substrates S in a manner described below, the carbon-containing protective film is formed on the SiN film. The SiN film may be formed by, for example, ALD. The SiN film may also be formed by CVD.

First, the interior of the first chamber 1 is set to have a desired temperature of, for example, 600 degrees C or less, the substrate holder 5 on which 50 to 175 substrates S are placed is loaded into the first chamber 1, and an internal pressure of the first chamber 1 is adjusted to a desired vacuum pressure while the interior of the first chamber 1 is exhausted by the exhaust device 4.

Next, the supply of the Si raw material gas into the first chamber 1 from the Si raw material gas supply mechanism 14, and the supply of the plasmarized nitrogen-containing gas into the first chamber 1 from the nitrogen-containing gas supply mechanism 15 via the plasma generation mechanism 30 are repeated multiple times. Thus, the SiN film is formed by ALD, which alternately performs an adsorption process of the Si raw material gas onto the substrate S and a nitridation process of the adsorbed Si raw material gas. After one round of adsorption process of the Si raw material gas and after one round of nitridation process, the inert gas is supplied into the first chamber 1 from the inert gas supply mechanism 29 to purge a residual gas in the interior of the first chamber 1. In the case of forming the SiN film by CVD, the Si raw material gas and the nitrogen-containing gas are supplied simultaneously.

After the SiN film is formed, the interior of the first chamber 1 is purged, and the carbon-containing protective film is formed. The film formation of the carbon-containing protective film is performed by plasmarizing the carbon-containing gas supplied from the carbon-containing gas supply mechanism 16 by the plasma generation mechanism 30 and supplying the plasmarized carbon-containing gas into the first chamber 1, and by CVD. In addition, the carbon-containing protective film may be formed without plasmarizing the carbon-containing gas.

### Example of Single-Wafer-Type Modification Apparatus

Next, an example of the single-wafer-type modification apparatus 102 will be described.

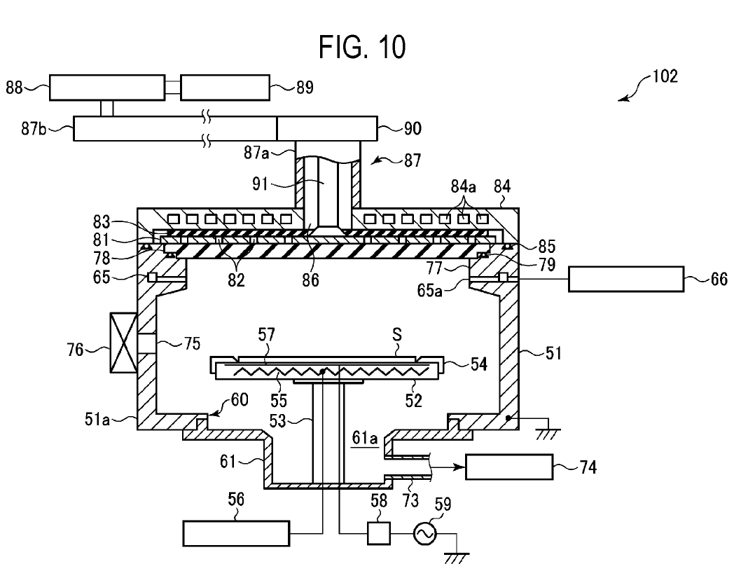

FIG. 10 is a cross-sectional view illustrating the example of the single-wafer-type modification apparatus 102.

The single-wafer-type modification apparatus 102 in this example is a microwave plasma processing apparatus and is configured as an RLSA (registered trademark) microwave plasma processing apparatus.

As illustrated in FIG. 10, the single-wafer-type modification apparatus 102 includes a substantially grounded airtight cylindrical second chamber 51. A circular opening 60 is formed in a substantially central portion of a bottom wall 51a of the second chamber 51. An exhaust chamber 61 is provided in the bottom wall 51a to communicate with the opening 60 and protrude downward.

A substrate stage 52 for horizontally supporting the substrate S is provided inside the second chamber 51. The substrate stage 52 is made of ceramics such as AlN, and is supported by a cylindrical support member 53 extending upward from the bottom center of the exhaust chamber 61. A guide ring 54 for guiding the substrate S is provided on an outer edge portion of the substrate stage 52. Further, a resistance heater 55 is embedded in the substrate stage 52. The heater 55 is supplied with power from a heater power supply 56 to heat the substrate stage 52 and control a temperature of the substrate S placed thereon. Further, an electrode 57 is embedded in the substrate stage 52. A radio-frequency power supply 59 for bias application is connected to the electrode 57 via a matcher 58.

A substrate support pins (not illustrated) for supporting and vertically moving the substrate S is provided on the substrate stage 52 so as to be capable of moving upward and downward with respect to the surface of the substrate stage 52.

An annular gas introducer 65 is provided in the sidewall of the second chamber 51. A plurality of gas emission holes 65a are evenly formed in the gas introducer 65. A gas supply mechanism 66 is connected to the gas introducer 65.

The gas supply mechanism 66 supplies a noble gas, which is a plasma generation gas and is used for the plasma modification processing. In addition, the gas supply mechanism 66 may supply a chemical gas for the plasma modification processing, or an oxygen-free gas used for the plasma ashing to remove the carbon-containing protective film. In a case in which an H₂ gas or a NH₃ gas is used as the chemical gas for the plasma modification processing, they may also be used as the oxygen-free gas for the plasma ashing. In a case in which a plurality of gases are supplied from the gas supply mechanism 66, they are supplied to the gas introducer 65 via separate pipes while flow rates thereof are independently controlled by respective flow-rate controllers such as mass flow controllers.

An exhaust pipe 73 is connected to a side surface of the exhaust chamber 61. An exhaust device 74, which includes a vacuum pump, an automatic pressure control valve, and the like, is connected to the exhaust pipe 73. By operating the vacuum pump of the exhaust device 74, a gas inside the second chamber 51 is uniformly discharged into a space 61a of the exhaust chamber 61 and exhausted via the exhaust pipe 73, so that the interior of the second chamber 51 may be controlled to have a predetermined degree of vacuum by the automatic pressure control valve.

A loading/unloading port 75 for loading or unloading the substrate S therethrough and a gate valve 76 for opening or closing the loading/unloading port 75 are provided in the sidewall of the second chamber 51.

An upper portion of the second chamber 51 functions as an opening. A peripheral edge portion of the opening serves as a ring-shaped support 77. A disk-shaped microwave transmission plate 78, which is formed of a dielectric, for example, quartz or ceramics such as Al₂O₃, is airtightly provided on the support 77 via a sealing member 79. Accordingly, the interior of the second chamber 51 is kept airtight.

A disk-shaped planar antenna 81 corresponding to the microwave transmission plate 78 is provided above the microwave transmission plate 78 so as to come into close contact with the microwave transmission plate 78. The planar antenna 81 is locked into an upper end of the sidewall of the second chamber 51. The planar antenna 81 is constituted as a disk made of a conductive material. Specifically, for example, the planar antenna is formed of a copper plate or aluminum plate having a surface plated with silver or gold. A large number of microwave radiation holes 82 (slots) are formed to penetrate the planar antenna in a predetermined pattern. As an example of the pattern, a plurality of pairs of microwave radiation holes 82, each pair including two microwave radiation holes 82 arranged in a T shape, may be arranged concentrically. A length and arrangement interval of the microwave radiation holes 82 are determined according to a wavelength (λg) of microwaves. For example, the microwave radiation holes 82 are arranged so that the interval thereof is λg/4, λg/2, or λg. In addition, the microwave radiation holes 82 may have other shapes such as a circular shape or an arc shape. Further, an arrangement form of the microwave radiation holes 82 is not particularly limited. In addition to the aforementioned concentric arrangement, the microwave radiation holes 82 may be arranged in, for example, a spiral shape or a radial shape.

A slow-wave member 83, which is made of a dielectric having a dielectric constant greater than that of vacuum, for example, quartz, polytetrafluoroethylene, polyimide or the like, is provided in close contact with an upper surface of the planar antenna 81. The slow-wave member 83 has a function of shortening the wavelength of microwaves compared to that in vacuum, thereby downsizing the planar antenna 81. The slow-wave member 83 may adjust a phase of the microwaves according to the thickness thereof, and may maximize radiation energy of the microwaves by adjusting the thickness thereof so that a junction of the planar antenna 81 becomes an "antinode" of standing waves.

In addition, the planar antenna 81 and the microwave transmission plate 78, and the slow-wave member 83 and the planar antenna 81 are respectively arranged in close contact with each other, but may be arranged to be spaced apart from each other.

A shield cover 84, which is made of a metallic material such as aluminum, stainless steel, or copper, is provided on the upper surface of the second chamber 51 so as to cover the planar antenna 81 and the slow-wave member 83. The upper surface of the second chamber 51 and the shield cover 84 are sealed from each other by a sealing member 85. A cooling-water flow path 84a is formed in the shield cover 84. By flowing cooling water through the cooling-water flow path 84a, the shield cover 84, the slow-wave member 83, the planar antenna 81, and the microwave transmission plate 78 are cooled. In addition, the shield cover 84 is grounded.

An opening 86 is formed the center of in an upper wall of the shield cover 84. A waveguide 87 is connected to the opening 86. A microwave generation device 89 is connected to an end portion of the waveguide 87 via a matching circuit 88. Thus, microwaves having a frequency of, for example, 2.45 GHz, which are generated by the microwave generation device 89, are propagated to the planar antenna 81 via the waveguide 87. In addition, various frequencies such as 8.35 GHz, 1.98 GHz, 860 MHz, and 915 Mhz may be used as the frequency of the microwaves.

The waveguide 87 includes a coaxial waveguide 87a having a circular cross-section extending upward from the opening 86 of the shield cover 84, and a rectangular waveguide 87b extending in the horizontal direction and connected to an upper end portion of the coaxial waveguide 87a via a mode converter 90. The mode converter 90 between the rectangular waveguide 87b and the coaxial waveguide 87a has a function of converting microwaves propagating in a TE mode inside the rectangular waveguide 87b into ones in a TEM mode. An inner conductor 91 extends in the center of the coaxial waveguide 87a. A lower end portion of the inner conductor 91 is connected and fixed to the center of the planar antenna 81. Thus, the microwaves are propagated uniformly and efficiently to the planar antenna 81 via the inner conductor 91 of the coaxial waveguide 87a.

In the single-wafer-type modification apparatus 102 configured as above, first, the gate valve 76 is opened so that the substrate S is loaded into the second chamber 51 from the loading/unloading port 75 and is placed on the substrate stage 52.

Then, the noble gas, which is a plasma generation gas, for example, an Ar gas, is introduced into the second chamber 51 from the gas supply mechanism 66 via the gas introducer 65, and microwaves of a predetermined power from the microwave generation device 89 are guided to the waveguide 87 via the matching circuit 88. The microwaves guided to the waveguide 87 are propagated in the TE mode through the rectangular waveguide 87b. The microwaves in the TE mode are converted into ones in the TEM mode by the mode converter 90. The microwaves in the TEM mode are propagated in the TEM mode through the coaxial waveguide 87a. Then, the microwaves in the TEM mode pass through the slow-wave member 83, the slots 82 of the planar antenna 81, and the microwave transmission plate 78, and are radiated into the second chamber 51. The microwaves diffuse only in a region directly below the microwave transmission plate 78 as surface waves, thereby generating a surface-wave plasma. Then, the plasma diffuses downward, and becomes plasma at high electron density and low electron temperature in a region where the substrate S is arranged.

In the case in which the carbon-containing protective film is removed by the plasma ashing, a radio-frequency bias for ion introduction is applied to the substrate stage 52 from the radio-frequency power supply 59. Further, a reducing gas such as an H₂ gas or a NH₃ gas, or an oxygen-free gas such as an N₂ gas is supplied from the gas supply mechanism 66 via the gas introducer 65 and is plasmarized, so that the carbon-containing protective film is removed by ashing.

In the case in which the plasma modification processing is performed, the radio-frequency bias for ion introduction is applied to the substrate stage 52 from the radio-frequency power supply 59. Further, the noble gas alone or a mixture of the noble gas and the chemical gas such as the H₂ gas or the NH₃ gas is supplied from the gas supply mechanism 66 via the gas introducer 65 and is plasmarized to perform the plasma modification processing. As described above, the plasma modification processing may be performed after removing the carbon-containing protective film, or may be performed in a state in which the carbon-containing protective film remains.

According to the present disclosure, there are provided a film forming method and a film forming system which are capable of forming a compound film such as a SiN film with high productivity at good film quality.

### Other Applications

Although the embodiments have been described above, the embodiments disclosed herein should be considered to be exemplary and not restrictive in all respects. The above embodiments may be omitted, replaced, or modified in various ways without departing from the scope and spirit of the appended claims.

For example, in the above embodiments, the nitrogen-containing film or the oxygen-carbon-containing film was exemplified as the finally-obtained film, but the present disclosure is not limited thereto. Further, a method of forming the compound film, a method of forming the carbon-containing protective film, a method of removing the carbon-containing protective film, and a method of modifying the compound film are not limited to those exemplified in the embodiments. Further, in the above embodiments, the plasma-assisted vertical batch-type film forming apparatus was illustrated as the batch-type film forming apparatus, but the present disclosure is not limited thereto. An apparatus using no plasma may be used. Further, an apparatus using a microwave plasma was illustrated as the single-wafer-type modification apparatus, but the present disclosure is not limited thereto. Another plasma such as a capacitively coupled plasma or an inductively coupled plasma may be used, or no plasma may be used.

What is claimed is:

1. A film forming method of performing film formation using a batch-type film forming apparatus including a first chamber and a single-wafer-type modification apparatus including a second chamber, the film forming method comprising:
loading a plurality of substrates into the first chamber;
forming a compound film on each of the plurality of substrates loaded into the first chamber;
forming a carbon-containing protective film on each of the plurality of substrates inside the first chamber;
unloading, from the first chamber, the plurality of substrates on each of which the carbon-containing protective film has been formed;
loading one or several substrates, among the plurality of substrates unloaded from the first chamber, into the second chamber of the single-wafer-type modification apparatus; and
performing modification processing on the one or several substrates inside the second chamber,
wherein a modified film is formed on the one or several substrates by the performing the modification processing.

2. The film forming method of claim 1, wherein the batch-type film forming apparatus performs processing on the plurality of substrates arranged inside the first chamber, wherein the plurality of substrates includes 50 or more substrates, and the single-wafer-type modification apparatus performs processing on the one or several substrates placed on a stage inside the second chamber, wherein the one or several substrates includes four or less substrates.

3. The film forming method of claim 1, further comprising: removing the carbon-containing protective film inside the second chamber to expose the compound film,
wherein, after the removing the carbon-containing protective film, the modification processing is performed on the one or several substrates.

4. The film forming method of claim 3, wherein the removing the carbon-containing protective film to expose the compound film is performed by plasma ashing using an oxygen-free gas.

5. The film forming method of claim 3, wherein the compound film is a nitrogen-containing film or an oxygen-carbon-containing film.

6. The film forming method of claim 5, wherein the compound film is any one of a SiN film, a SiCN film, a SiON film, a SiOCN film, a BN film, a BCN film, and a SiOC film.

7. The film forming method of claim 1, wherein the modification processing is performed while the carbon-containing protective film remains on each of the one or several substrates.

8. The film forming method of claim 7, wherein, in the performing the modification processing, the modified film is formed in a state in which carbon from the carbon-containing protective film is mixed with the compound film.

9. The film forming method of claim 8, wherein the compound film is determined in composition such that the modified film is a nitrogen-containing film or an oxygen-carbon-containing film.

10. The film forming method of claim 9, wherein the compound film is any one of a SiN film, a SiCN film, a SiON film, a SiOCN film, a BN film, a BCN film, a SiOC film, and a SiO film.

11. The film forming method of claim 1, wherein a thickness of the carbon-containing protective film is in a range of 10 nm to 100 nm.

12. The film forming method of claim 1, wherein the plurality of substrates unloaded from the first chamber are exposed to atmosphere.

13. The film forming method of claim 1, wherein the forming the compound film is performed using a plasma-assisted ALD process.

14. The film forming method of claim 13, wherein the forming the compound film is performed using, as the batch-type film forming apparatus, a vertical-type film forming apparatus configured to perform the film formation in a state in which the plurality of substrates stacked one above another in a vertical direction are placed inside the first chamber.

15. The film forming method of claim 14, wherein plasma in the plasma-assisted ALD process is a remote plasma.

16. The film forming method of claim 13, wherein the forming the carbon-containing protective film is performed using a plasma-assisted CVD process by supplying a gas containing carbon into the first chamber.

17. The film forming method of claim 1, wherein the performing the modification processing is performed by a plasma-based modification processing.

18. The film forming method of claim 17, wherein the plasma-based modification processing uses a noble gas, or a gas obtained by adding one of a H₂ gas, a NH₃ gas, a N₂ gas, and a hydrocarbon gas to the noble gas.

19. A film forming system comprising:
a batch-type film forming apparatus including a first chamber and configured to process a plurality of substrates;
a single-wafer-type modification apparatus including a second chamber and configured to process one or several substrates;
a transfer device configured to transfer the substrates; and
a control device,
wherein the control device controls the batch-type film forming apparatus, the single-wafer-type modification apparatus, and the transfer device to execute:
loading the plurality of substrates into the first chamber;
forming a compound film on each of the plurality of substrates loaded into the first chamber;
forming a carbon-containing protective film on each of the plurality of substrates inside the first chamber;
unloading, from the first chamber, the plurality of substrates on each of which the carbon-containing protective film has been formed;
loading the one or several substrates, among the plurality of substrates unloaded from the first chamber, into the second chamber of the single-wafer-type modification apparatus; and
performing modification processing on the one or several substrates inside the second chamber.

20. A film forming system which forms a compound film on each of a plurality of substrates, comprising:
a batch-type film forming apparatus including a first chamber and configured to process the plurality of substrates; and
a single-wafer-type modification apparatus including a second chamber and configured to process one or several substrates among the plurality of substrates,
wherein the compound film is formed on each of the plurality of substrates inside the first chamber, a carbon-containing protective film is formed on each of the plurality of substrates on each of which the compound film has been formed inside the first chamber, the one or several substrates among the plurality of substrates on each of which the carbon-containing protective film has been formed and which have been unloaded from the first chamber are loaded into the second chamber of the single-wafer-type modification apparatus, and modification processing is performed on the one or several substrates inside the second chamber.
